(19) United States
(12) Patent Application Publication
(10) Pub. No.: US 2025/0385067 A1
(43) Pub. Date: Dec. 18, 2025

(54) METHOD FOR OPERATING A PARTICLE BEAM APPARATUS, COMPUTER PROGRAM PRODUCT AND PARTICLE BEAM APPARATUS FOR CARRYING OUT THE METHOD

(71) Applicant: Carl Zeiss Microscopy GmbH, Jena (DE)

(72) Inventors: Marko MATIJEVIC, Nuertingen (DE); Armin HAYN, Saffron Walden (GB)

(73) Assignee: Carl Zeiss Microscopy GmbH, Jena (DE)

(21) Appl. No.: 19/235,667

(22) Filed: Jun. 12, 2025

(30) Foreign Application Priority Data
Jun. 14, 2024 (DE) 10 2024 116 875.7

(51) Int. Cl. H01J 37/153; H01J 37/14; H01J 37/147; H01J 37/26; H01J 37/28

(52) U.S. Cl. CPC H01J 37/153; H01J 37/14; H01J 37/1472; H01J 37/265; H01J 37/28; H01J 2237/1534

(57) ABSTRACT

Operating a particle beam apparatus for imaging, analyzing and/or processing an object includes defining a working distance, guiding and/or shaping a particle beam to generate a first cross-over of the particle beam in the objective lens using a condenser lens, guiding and/or shaping the particle beam to generate a second cross-over of the particle beam using the objective lens, and deflecting the particle beam to a position associated with the working distance along an optical axis of the particle beam apparatus depending on the working distance using a deflection device arranged within the objective lens. The second cross-over is arrangeable on the object. The deflection device is controlled with control signals in such a way that aberrations generated by the objective lens are reduced. A computer program product and/or a particle beam apparatus may may be used for the imaging, analyzing and/or processing of the object.

### CROSS-REFERENCE TO RELATED APPLICATIONS

This application claims the priority of German patent application No. 10 2024 116 875.7, filed on 14 Jun. 2024, which is incorporated by reference herein.

### TECHNICAL FIELD

This application relates to operating a particle beam apparatus for imaging, analysing and/or processing an object.

### BACKGROUND

Electron beam apparatuses, in particular a scanning electron microscope (also referred to as SEM below) and/or a transmission electron microscope (also referred to as TEM below), are used to examine objects (also referred to as samples below) in order to gain insight into the properties and the behaviour under certain conditions.

In an SEM, an electron beam (also referred to as primary electron beam below) is generated using a beam generator and focused on an object to be examined by way of a beam guiding system. The primary electron beam is guided over a surface of the object to be examined using a deflection device in the form of a scanning device. In the process, the electrons of the primary electron beam interact with the object to be examined. As a consequence of the interaction, electrons, in particular, are emitted by the object (so-called secondary electrons), and electrons of the primary electron beam are backscattered (so-called backscattered electrons). The secondary electrons and the backscattered electrons are detected and used for image generation. An image representation of the object to be examined is thus obtained. Furthermore, interaction radiation, for example x-ray radiation or cathodoluminescence, is generated during the interaction, and the interaction radiation is detected using a detector and subsequently evaluated in order to analyse the object.

In the case of a TEM, a primary electron beam is likewise generated using a beam generator and guided onto an object to be examined using a beam guiding system. The primary electron beam radiates through the object to be examined. When the primary electron beam passes through the object to be examined, the electrons of the primary electron beam interact with the material of the object to be examined. The electrons passing through the object to be examined are imaged on a luminescent screen or on a detector (for example a camera) by a system consisting of an objective and a projection unit. Here, imaging may also take place in the scanning mode of a TEM. Usually, such a TEM is referred to as STEM. Additionally, the use of a further detector to detect electrons backscattered at the object to be examined and/or secondary electrons emitted by the object to be examined may be provided, in order to image an object to be examined.

Combining the function of a STEM and an SEM in a single particle beam apparatus is known. This particle beam apparatus can thus be used to carry out examinations of objects with an SEM function and/or with a STEM function.

Moreover, a particle beam apparatus with an ion beam column is known. Ions used for processing an object are generated using an ion beam generator arranged in the ion beam column. For example, material of the object is ablated, or material is applied to the object during the processing, for example with a gas being supplied. In addition or as an alternative thereto, the ions are used for imaging.

Furthermore, the prior art has disclosed the use of combination apparatuses for examining objects, in which both electrons and ions may be guided onto an object to be examined. For example, additionally equipping an SEM with an ion beam column is known. An ion beam generator arranged in the ion beam column is used to generate ions that are used for the preparation of an object (for example ablating material from the object or applying material to the object) or else for imaging. For this purpose, the ions are scanned over the object using a deflection device in the form of a scanning device. The SEM serves here in particular to observe the preparation, but also for further examination of the prepared or unprepared object.

When an image of an object is generated, imaging of an object can be implemented using a particle beam apparatus with a high spatial resolution. In particular, this is achieved by a very small diameter of the primary electron beam in the plane of the object. Furthermore, the spatial resolution may improve the more the electrons of the primary electron beam are initially accelerated in the particle beam apparatus and decelerated to a desired energy (referred to as landing energy) at the end in the objective lens or in the region between the objective lens and the object. For example, the electrons of the primary electron beam are accelerated using an acceleration voltage of 2 kV to 30 kV and guided through an electron beam column of a particle beam apparatus. The electrons of the primary electron beam are only decelerated to the desired landing energy, with which the electrons are incident on the object, in the region between the objective lens and the object. For example, the landing energy of the electrons in the primary electron beam lies in the range of 10 eV to 30 keV.

In order to scan a particle beam over an object, it is known to arrange a scanning device on a particle beam apparatus. For example, the scanning device is embodied as a deflection device. The deflection device includes a first deflection unit and a second deflection unit, where the first deflection unit and the second deflection unit are arranged one after the other along the optical axis of the particle beam apparatus. The position of a virtual tilting point of the particle beam along the optical axis of the particle beam apparatus can be displaced by combining the deflections of the particle beam which can be achieved by the first deflection unit and the second deflection unit, where the deflection appears virtually as generated by a tilt about the virtual tilting point.

Operating a particle beam apparatus in a so-called “fisheye mode” is known, in order to generate a large image of an object (for example in the form of a large semiconductor wafer). The large image is used, for example, to navigate the object and/or some other assembly of the particle beam apparatus with respect to the object in a sample chamber of the particle beam apparatus. To achieve the “fisheye mode”, for example, the first deflection unit and the second deflection unit generate deflections in the same direction. This provides a fairly large overview image of the object. In other words, the fisheye mode provides a fairly large image field of the particle beam apparatus. Furthermore, it is known to strongly excite an objective lens of the particle beam apparatus in order to achieve the fisheye mode. In this way, large deflection angles are achieved for the particle beam focused with the objective lens, and so a large region of the object can be imaged. However, the fisheye mode, which provides large deflection angles for the particle beam, often generates aberrations that are visible in the generated image of the large region of the object. The aberrations may cause errors in the navigation of the object and/or the other assemblies of the particle beam apparatus with respect to the object in the sample chamber.

As regards the prior art, reference is made to DE 10 2010 053 194 A1 and DE 10 2011 076 893 A1.

### SUMMARY OF THE INVENTION

The problem addressed by the system described herein is that of specifying a method and a particle beam apparatus for carrying out the method which, in the case of different operating modes of the particle beam apparatus, always make it possible to attain such a large image field of the particle beam apparatus that navigation of the object and/or some other assembly of the particle beam apparatus with respect to the object in a sample chamber of the particle beam apparatus with few errors is made possible.

The method according to the system described herein serves to operate a particle beam apparatus for imaging, analysing and/or processing an object. The particle beam apparatus includes at least one beam generator that generates a particle beam having charged particles. For example, the charged particles are electrons or ions. Moreover, the particle beam apparatus includes an objective lens that guides and/or shapes the particle beam, in particular for focusing the particle beam on the object. In the region between the beam generator and the objective lens, at least one condenser lens is arranged along an optical axis of the particle beam apparatus.

The method according to the system described herein includes defining a distance using a control device of the particle beam apparatus. The distance is given either (a) by an object distance between an outer boundary of the objective lens of the particle beam apparatus and the object or (b) by a focal plane distance between the outer boundary of the objective lens of the particle beam apparatus and a focal plane of the objective lens. The abovementioned distance according to case (a) or case (b) is also referred to as working distance. Options for defining the distance are explained in more detail further below.

Moreover, the method according to the system described herein includes guiding and/or shaping the particle beam to generate a first cross-over in the objective lens using the condenser lens arranged between the beam generator and the objective lens. To generate the first cross-over, the condenser lens is controlled with a predefinable value of a condenser lens current using the control device. A cross-over is understood to mean herein a point or a region at which the particles generated by the beam generator converge. In other words, the particles converge at a particular point or a particular region that is the cross-over. To put it in yet another way, a cross-over is understood to mean a region or a plane in which the dimensions of the particle beam emanating from the beam generator have a local minimum in directions perpendicular to the direction of propagation of the particle beam. If the particle beam has an approximate Gaussian distribution perpendicular to the direction of propagation, then a cross-over along the direction of propagation is a region in which the Gaussian bell curve has the smallest width. Upstream and downstream of the cross-over—as viewed in the beam direction (direction of propagation)—the width of the bell curve is thus in each case wider than in the cross-over. In the case of an astigmatic focusing of the particle beam, the cross-over is usually understood to mean that plane between the two (or between two) line foci in which the particle beam has a rotationally symmetrical intensity distribution with minimal dimensions perpendicular to the direction of propagation of the particle beam.

Moreover, the method according to the system described herein includes guiding and/or shaping the particle beam using the objective lens in such a way that a second cross-over of the particle beam, the second cross-over being arrangeable on the object, is generated. For this purpose, the objective lens is controlled with a predefinable value of an objective lens current using the control device. In this respect, two cross-overs are generated in the method according to the system described herein: in the first instance the first cross-over and in the second instance the second cross-over. As viewed from the beam generator in the direction of the object, firstly the first cross-over and then the second cross-over are arranged along the optical axis of the particle beam apparatus.

The particle beam apparatus includes a deflection device arranged within the objective lens and provided with at least one first deflection unit and with at least one second deflection unit. For example, the deflection device is embodied as a scanning device of the particle beam apparatus. As viewed in the direction of the objective lens proceeding from the beam generator, firstly the first deflection unit and then the second deflection unit are arranged along the optical axis. For example, the first deflection unit and/or the second deflection unit are/is arranged within the objective lens of the particle beam apparatus. In particular, provision is made for the first deflection unit and/or the second deflection unit to be arranged within the objective lens along the optical axis of the particle beam apparatus. The first deflection unit is embodied, for example, as an electrostatic and/or magnetic deflection unit. In addition, provision is made, for example, for the second deflection unit to be embodied as an electrostatic and/or magnetic.

The method according to the system described herein provides for deflecting the particle beam generated by the beam generator of the particle beam apparatus to a position along the optical axis of the particle beam apparatus depending on the defined distance (i.e. the defined working distance) using the deflection device. Accordingly, the position is associated with the defined distance. In other words, the particle beam is guided by the deflection device to the position along the optical axis of the particle beam apparatus depending on the defined working distance. The abovementioned position of the particle beam along the optical axis of the particle beam apparatus is, for example, the tilting point of the particle beam explained further above. Furthermore, the abovementioned position of the particle beam along the optical axis is arranged within the second deflection unit. The deflection device is controlled with control signals using the control device of the particle beam apparatus in such a way that aberrations generated by the objective lens are reduced. The generated aberrations of the objective lens are smaller in comparison with the aberrations of the objective lens generated if the particle beam were not deflected to the abovementioned position. Ideally, the deflection device is controlled with control signals using the control device of the particle beam apparatus in such a way that aberrations generated by the objective lens are avoided.

In the case of the system described herein, the aberrations generated by the objective lens are reduced or, ideally, completely avoided using the abovementioned generation of the first cross-over and the second cross-over and using the abovementioned deflection of the particle beam to the position along the optical axis of the particle beam apparatus. Accordingly, it is possible to attain a large image field which has smaller aberrations and/or no aberrations in comparison with the prior art. Consequently, on account of the system described herein, in the case of different operating modes of the particle beam apparatus, it is always possible to attain such a large image field of the particle beam apparatus that navigation of the object and/or some other assembly of the particle beam apparatus with respect to the object in a sample chamber of the particle beam apparatus with few errors is made possible.

For example, provision is made for the first cross-over to be arranged in the region of a pole piece gap of a pole piece of the objective lens. In particular, provision is made for the first cross-over and/or the second deflection unit to be arranged in the region of the pole piece gap of the pole piece of the objective lens.

One embodiment of the method according to the system described herein additionally or alternatively provides for the deflection device to be controlled using the control device of the particle beam apparatus in such a way that the aberrations generated by the objective lens are minimal.

A further embodiment of the method according to the system described herein additionally or alternatively provides for the first deflection unit to be controlled with a first control signal using the control device. Furthermore, the second deflection unit is controlled with a second control signal using the control device. The position of the particle beam associated with the defined distance is determined by the ratio of the first control signal to the second control signal. In other words, the position associated with the defined distance is dependent on the ratio of the first control signal to the second control signal.

In yet another embodiment of the method according to the system described herein, provision is additionally or alternatively made for a landing energy with which the particles of the particle beam are incident on the object to be adjusted and/or ascertained using the control device. For example, ascertaining the landing energy includes measuring the landing energy and/or reading the landing energy from a landing energy measuring device. The predefinable value of the objective lens current and/or of the condenser lens current are/is selected depending on the landing energy. Accordingly, the first cross-over in this embodiment is also dependent on the landing energy of the particles of the particle beam; the second cross-over always lies at the location of the object, independently of the landing energy of the particles of the particle beam. For example, in the embodiment of the method according to the system described herein, a control device includes an acceleration device and/or deceleration device for the particles of the particle beam is used as the control device.

In yet another embodiment of the method according to the system described herein, provision is additionally or alternatively made for defining the distance to be effected by adjusting the predefinable value of the condenser lens current, where the predefinable value of the objective lens current is not changed. Accordingly, in this embodiment of the method according to the system described herein, adjusting the working distance is effected exclusively by the condenser lens. The objective lens current is kept constant. In other words, the objective lens current is thus not changed.

In one embodiment of the method according to the system described herein, provision is additionally or alternatively made for defining the distance (i.e. defining the working distance) according to case (a) to be effected by a relative movement of the object with respect to the objective lens and/or by ascertaining the object distance. Ascertaining the object distance includes, for example, measuring the object distance and/or reading the object distance on a measuring device. In yet another embodiment of the method according to the system described herein, provision is additionally or alternatively made for defining the distance according to case (b) to be effected by controlling the objective lens for positioning a focal plane of the objective lens and/or by ascertaining the focal plane distance.

Ascertaining the focal plane distance includes, for example, measuring the focal plane distance and/or reading the focal plane distance on the measuring device.

In a further embodiment of the method according to the system described herein, provision is additionally or alternatively made for the distance (i.e. the working distance) to be defined using at least one of the following method steps: (i) moving an object holder, on which the object is arranged, along the optical axis of the particle beam apparatus; (ii) moving the object holder, on which the object is arranged, relative to the optical axis of the particle beam apparatus, the movement not being perpendicular to the optical axis; (iii) moving the objective lens of the particle beam apparatus along the optical axis of the particle beam apparatus using a movement device; and (iv) moving the objective lens of the particle beam apparatus relative to the optical axis using the movement device, the movement not being perpendicular to the optical axis.

In yet another embodiment of the method according to the system described herein, provision is additionally or alternatively made for the position of the particle beam along the optical axis, associated with the defined distance (i.e. with the defined working distance), to be calculated using the control device. For example, the associated position can be calculated using a simulation of the course of the particle beam under predefinable and adjustable conditions. The conditions include, for example, values of control parameters for assemblies of the particle beam apparatus which make it possible to influence the course of the particle beam in the particle beam apparatus and/or the shape of the particle beam. In particular, calculations with a linear approximation or a method which is also known as “ray tracing” can be used in the simulation. For example, after calculating the position associated with the defined distance, the particle beam is deflected to the position along the optical axis of the particle beam apparatus using the deflection device.

In yet another embodiment of the method according to the system described herein, provision is additionally or alternatively made for the associated position of the particle beam along the optical axis to also change when the defined distance (i.e. the defined working distance) changes. Thus, in this embodiment of the method according to the system described herein, the defined distance is a first distance, the associated position of the particle beam along the optical axis is a first associated position, the object distance is a first object distance, the focal plane distance is a first focal plane distance and the predefinable value of the condenser lens current is a first predefinable value of the condenser lens current. This embodiment of the method according to the system described herein includes the following method steps:
defining a second distance using the control device of the particle beam apparatus, where the second distance is greater or less than the first distance, and where the second distance is given either (c) by a second object distance between the outer boundary of the objective lens of the particle beam apparatus and the object, or (d) by a second focal plane distance between the outer boundary of the objective lens of the particle beam apparatus and the focal plane of the objective lens;
guiding and/or shaping the particle beam using the condenser lens in such a way that a further first cross-over of the particle beam is generated in the objective lens. For this purpose, the condenser lens is controlled with a further predefinable value of a condenser lens current using the control device;
the value of the objective lens current is not changed in this embodiment of the method according to the system described herein. Guiding and/or shaping the particle beam are/is effected using the objective lens in such a way that a further second crossover of the particle beam is generated at the object;
deflecting the particle beam generated by the beam generator of the particle beam apparatus to a second position along the optical axis of the particle beam apparatus depending on the defined second distance (i.e. the defined second working distance) using the deflection device. Accordingly, the second position is associated with the defined second distance. In other words, the particle beam is guided by the deflection device to the second position along the optical axis of the particle beam apparatus depending on the defined second working distance. The abovementioned second position of the particle beam along the optical axis of the particle beam apparatus is, for example, a further tilting point of the particle beam. Furthermore, the abovementioned second position of the particle beam along the optical axis is arranged within the second deflection unit. In this embodiment of the method according to the system described herein, too, the deflection device is controlled with further control signals using the control device of the particle beam apparatus in such a way that the aberrations generated by the objective lens are reduced in a predefinable manner. In the case of the system described herein, the aberrations generated by the objective lens are reduced or, ideally, avoided using the abovementioned generation of the further first cross-over and the further second cross-over and using the abovementioned deflection of the particle beam to the second position along the optical axis of the particle beam apparatus. Reference is made to the explanations given further above in regard to reducing the aberrations, which are applicable, mutatis mutandis, here as well. Accordingly, in this embodiment, too, it is possible to attain a large image field which has smaller aberrations and/or no aberrations in comparison with the prior art.

For example, provision is made for the further first cross-over to be arranged in the region of the pole piece gap of the pole piece of the objective lens.

In one embodiment of the method according to the system described herein, provision is additionally or alternatively made for the first position and/or the second position to move closer to the object, the greater the working distance becomes.

In one embodiment of the method according to the system described herein, provision is additionally or alternatively made for the position of the particle beam along the optical axis, associated with the defined distance (i.e. with the defined working distance), to be loaded from a database and/or from a storage unit into the control device. Deflecting the particle beam is then effected using the deflection device in such a way that the particle beam is guided to the loaded position. In other words, in this embodiment of the method according to the system described herein, provision is made for the position of the tilting point depending on the working distance to be stored in a database and/or in a storage unit. If the working distance has been defined, the associated position can be loaded from the database and/or the storage unit and set. The abovementioned embodiment of the method according to the system described herein is carried out, for example, for loading the abovementioned first position and/or second position.

In a further embodiment of the method according to the system described herein, provision is additionally or alternatively made for a central path of the particle beam at the position along the optical axis to have an axial distance perpendicular to the optical axis of the particle beam apparatus. At the defined distance, the axial distance of the central path of the particle beam at the position along the optical axis is smaller than all further axial distances of the central path of the particle beam perpendicular to the optical axis of the particle beam apparatus, where, for the defined distance according to case (a), the further axial distances are arranged between a centre of the second deflection unit of the deflection device and the object, and where, for the defined distance according to case (b), the further axial distances are arranged between the centre of the second deflection unit of the deflection device and the focal plane.

In yet another embodiment of the method according to the system described herein, provision is additionally or alternatively made for the objective lens excited with the objective lens current to generate a magnetic field. The magnetic field has a spatial distribution along the optical axis of the particle beam apparatus in the region of the objective lens. The spatial distribution of the magnetic field has a full width at half maximum. The first cross-over of the particle beam lies within the full width at half maximum of the spatial distribution. The second cross-over of the particle beam always lies at the location of the object. Additionally or alternatively, the associated position lies within the full width at half maximum of the spatial distribution. Considerations have revealed that when the first cross-over of the particle beam is arranged within the full width at half maximum of the spatial distribution of the magnetic field of the objective lens, the method according to the system described herein is carried out particularly well.

In yet another embodiment of the method according to the system described herein, provision is additionally or alternatively made for an electrostatic and/or magnetic deflection device to be used as the deflection device.

In one embodiment of the method according to the system described herein, provision is additionally or alternatively made for the particle beam to be defocused by the objective lens in such a way that a maximum deflection of the particle beam with respect to the optical axis of the particle beam apparatus is attained.

All embodiments of the method according to the invention described herein are not restricted to the explained order of the method steps. The invention also encompasses different orders of the method steps that are suitable for solving the problem within the meaning of the invention. Alternatively or additionally, in the method according to the invention, provision is also made to carry out at least two method steps in parallel. Furthermore, the embodiments of the method according to the invention described herein are not restricted to the complete scope of all the method steps mentioned herein. In particular, provision is made for individual or a plurality of the abovementioned or following method steps to be omitted in further embodiments.

The system described herein also relates to a computer program product having a program code which is loadable or is loaded into a processor of a particle beam apparatus, where the program code, when executed in the processor, controls the particle beam apparatus in such a way that a method having at least one of the abovementioned or following features or having a combination of at least two of the abovementioned or following features is carried out. In other words, the system described herein also relates to a non-volatile, computer-readable medium including software which is loadable or is loaded into a processor of a particle beam apparatus, where the software, when executed in the processor, controls the particle beam apparatus in such a way that a method having at least one of the abovementioned or following features or having a combination of at least two of the abovementioned or following features is carried out. The software includes executable code for carrying out at least one method step.

In this respect, the system described herein also relates to a processor arranged on a particle beam apparatus and configured to carry out a method having at least one of the abovementioned or following features or having a combination of at least two of the abovementioned or following features.

The system described herein furthermore relates to a particle beam apparatus for imaging, analysing and/or processing an object, where the particle beam apparatus is explained herein and specified in detail further below. The particle beam apparatus according to the system described herein includes at least one beam generator that generates a particle beam having charged particles. The charged particles are electrons or ions, for example.

Furthermore, the particle beam apparatus according to the system described herein includes at least one condenser lens that guides and/or shapes the particle beam on the object. Moreover, the particle beam apparatus according to the system described herein includes at least one objective lens that guides and/or shapes the particle beam, in particular for focusing the particle beam on the object. For example, the condenser lens is arranged in the region between the beam generator and the objective lens. Furthermore, the particle beam apparatus according to the system described herein includes at least one deflection device provided with at least one first deflection unit and with at least one second deflection unit. As viewed from the beam generator in the direction of the objective lens, firstly the first deflection unit and then the second deflection unit are arranged along the optical axis, for example. The first deflection unit and/or the second deflection unit are/is arranged within the objective lens of the particle beam apparatus. In particular, provision is made for the first deflection unit and/or the second deflection unit to be arranged within the objective lens along the optical axis of the particle beam apparatus. The first deflection unit is embodied, for example, as an electrostatic and/or magnetic deflection unit. In addition, provision is made, for example, for the second deflection unit to be embodied as an electrostatic and/or magnetic deflection unit. Furthermore, the method according to the system described herein includes at least one control device provided with at least one processor. A computer program product having the features discussed elsewhere herein is loaded into the processor.

In one embodiment of the particle beam apparatus according to the system described herein, provision is additionally or alternatively made for the first deflection unit to be arranged in the objective lens on a side of the objective lens directed towards the beam generator. Furthermore, provision is additionally or alternatively made for the second deflection unit to be arranged in the objective lens on a side of the objective lens directed towards the object.

In a further embodiment of the particle beam apparatus according to the system described herein, provision is additionally or alternatively made for the particle beam apparatus to include at least one detector unit for detecting interaction particles and/or interaction radiation resulting from an interaction of the particle beam with the object. In addition or as an alternative thereto, provision is made for the particle beam apparatus to include at least one acceleration device that accelerates the particles and/or a deceleration device that decelerates the particles in the particle beam apparatus.

In yet another embodiment of the particle beam apparatus according to the system described herein, provision is additionally or alternatively made for the particle beam apparatus to include a movable object holder, on which the object can be arranged. For example, the object holder is a movable object stage (a so-called stage). In addition or as an alternative thereto, provision is made for the particle beam apparatus according to the system described herein to include a movement device for moving the objective lens.

In yet another embodiment of the particle beam apparatus according to the system described herein, provision is additionally or alternatively made for the beam generator to be embodied as a first beam generator and for the particle beam to be embodied as a first particle beam having first charged particles. The objective lens is embodied as a first objective lens for focusing the first particle beam on the object. Furthermore, the particle beam apparatus according to the system described herein includes at least one second beam generator that generates a second particle beam having second charged particles. Moreover, the particle beam apparatus according to the system described herein includes at least one second objective lens that focuses the second particle beam on the object. The second charged particles are electrons or ions, for example.

In one embodiment of the particle beam apparatus according to the system described herein, provision is additionally or alternatively made for the first deflection unit and/or the second deflection unit to be embodied in a layer-like fashion. In particular, one embodiment provides for the first deflection unit and/or the second deflection unit to be embodied in a multilayered fashion. For example, magnetic units of the first deflection unit and/or of the second deflection unit are embodied in a multilayered fashion. In particular, the first deflection unit and/or the second deflection unit include(s) more than one layer of saddle coils for an x-direction and a y-direction in order to increase a deflection at a constant current. For example, the layers are connected in series.

A further embodiment of the particle beam apparatus according to the system described herein additionally or alternatively provides for the objective lens to include at least one pole piece provided with a pole piece gap. For example, the size and/or shape of the pole piece gap are/is adjustable. For this purpose, the objective lens has an adjusting device allowing the size and/or shape of the pole piece gap to be adjustable.

In particular, provision is made for the particle beam apparatus according to the system described herein to be embodied as an electron beam apparatus and/or as an ion beam apparatus.

### BRIEF DESCRIPTION OF DRAWINGS

Further practical embodiments and advantages of the system described herein are set forth below in association with the drawings, in which:

FIG. 1 shows a schematic illustration of a first embodiment of a particle beam apparatus according to the system described herein;

FIG. 2 shows a schematic illustration of a second embodiment of a particle beam apparatus according to the system described herein;

FIG. 3 shows a schematic illustration of a third embodiment of a particle beam apparatus according to the system described herein;

FIG. 4 shows a schematic illustration of an embodiment of a movable object stage according to the system described herein;

FIG. 5 shows a further schematic illustration of the embodiment of the movable object stage as per FIG. 4;

FIG. 6 shows a schematic illustration of an operation sequence of a first embodiment of the method according to the system described herein;

FIG. 7 shows a schematic illustration of an operation sequence of a second embodiment of the method according to the system described herein;

FIG. 8 shows a schematic illustration of an operation sequence of a third embodiment of the method according to the system described herein;

FIG. 9 shows a schematic illustration of an operation sequence of a fourth embodiment of the method according to the system described herein;

FIG. 10 shows a schematic illustration of an operation sequence of a fifth embodiment of the method according to the system described herein; and

FIG. 11 shows a schematic illustration of a magnetic field of an objective lens as a function of a z coordinate according to the system described herein.

### DESCRIPTION OF VARIOUS EMBODIMENTS

The system described herein will now be explained in more detail using particle beam apparatuses in the form of an SEM and in the form of a combination apparatus having an electron beam column and an ion beam column. Express reference is made to the fact that the invention can be used in any particle beam apparatus, in particular in any electron beam apparatus and/or any ion beam apparatus.

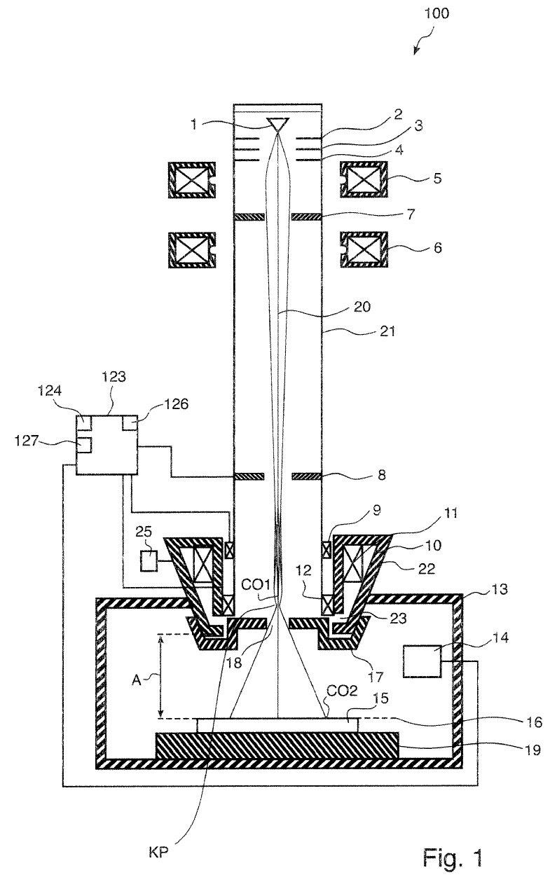

FIG. 1 shows a schematic illustration of one embodiment of a particle beam apparatus according to the system described herein in the form of an SEM 100. The SEM 100 includes a beam generator 1 having an electron source, an extraction electrode 2, a control electrode 3 and an anode 4. The anode 4 forms a source-side end of a beam guiding tube 21 of the SEM 100. The beam generator 1 is embodied as a thermal field emitter, for example. As an alternative thereto, the beam generator 1 is embodied as a thermal tungsten emitter or as an LaB₆ emitter, for example.

Electrons that emerge from the beam generator 1 form a primary electron beam. The electrons are accelerated to anode potential due to a potential difference between the beam generator 1 and the anode 4. The potential of the anode 4 is for example in the range of 1 kV to 30 KV positive relative to the potential of the beam generator 1, and so the electrons have a kinetic energy in the range of between 1 keV and 30 keV.

As viewed in the direction of an objective lens 10 along an optical axis 20 proceeding from the anode 4, the SEM 100 includes firstly a first condenser lens 5 and then a second condenser lens 6. An aperture unit 7 is arranged in the beam guiding tube 21 between the first condenser lens 5 and the second condenser lens 6. In the SEM 100 illustrated in FIG. 1, the objective lens 10 is embodied as a magnetic lens and includes a pole piece 22 with a pole piece gap 23. A ring coil 11 that generates the magnetic field of the objective lens 10 is arranged in the pole piece 22.

As viewed in the direction of the objective lens 10 proceeding from the second condenser lens 6, a deflection device having a first deflection unit 9 and a second deflection unit 12 is arranged along the optical axis 20 of the SEM 100. The first deflection unit 9 is arranged on the source side at least partly, in particular completely, within the objective lens 10. By contrast, the second deflection unit 12 is arranged on the object side on the beam guiding tube 21 within the objective lens 10. The first deflection unit 9 and the second deflection unit 12 are crossed beam deflection units, for example. In other words, both the first deflection unit 9 and the second deflection unit 12 are embodied in such a way that the deflection units 9, 12 deflect the primary electron beam in two directions which are not parallel to each other and are oriented perpendicular to the direction of the optical axis 20. For example, the first deflection unit 9 and/or the second deflection unit 12 are/is embodied as (a) magnetic deflection unit(s). In particular, the first deflection unit 9 and/or the second deflection unit 12 accordingly each includes(s), for example, four air coils arranged around the optical axis 20 of the SEM 100. However, the invention is not restricted to the aforementioned number of air coils. Rather, any number of air coils which is suitable for the invention can be used. In addition or as an alternative to that, provision is made for the first deflection unit 9 and/or the second deflection unit 12 to be embodied as (an) electrostatic deflection unit(s). In particular, the first deflection unit 9 and/or the second deflection unit 12 accordingly each include(s), for example, four electrodes which are arranged around the optical axis 20 of the SEM 100 and to which different electrostatic potentials can be applied. However, the invention is not restricted to the aforementioned number of electrodes. Rather, any number of electrodes that is suitable for the invention can be used.

In one embodiment of the SEM 100, provision is additionally or alternatively made for the first deflection unit 9 and/or the second deflection unit 12 to be embodied in a layer-like fashion. In particular, one embodiment provides for the first deflection unit 9 and/or the second deflection unit 12 to be embodied in a multilayered fashion. For example, magnetic units of the first deflection unit 9 and/or of the second deflection unit 12 are embodied in a multilayered fashion. In particular, the first deflection unit 9 and/or the second deflection unit 12 include(s) more than one layer of saddle coils for an x-direction and a y-direction in 20) order to increase a deflection at a constant current. For example, the layers are connected in series.

As explained above, the objective lens 10 has the pole piece 22 provided with a pole piece gap 23. For example, the size and/or shape of the pole piece gap 23 are/is adjustable. For this purpose, the objective lens 10 has an adjusting device allowing the size and/or shape 25 of the pole piece gap 23 to be adjustable. The second deflection unit 12 is arranged in the region of the pole piece gap 23 and/or at the pole piece gap 23.

The objective lens 10 is arranged on a sample chamber 13. In particular, the objective lens 10 protrudes through an opening of the sample chamber 13 into an interior of the sample chamber 13. A movable object stage 19 is arranged in the interior of the sample chamber 30 13. An object 15 can be arranged on the object stage 19.

Using the objective lens 10, the primary electron beam generated by the beam generator 1 and shaped using the first condenser lens 5 and/or the second condenser lens 6 is focused in an object plane 16. Suitable excitations of the first deflection unit 9 and the second deflection unit 12 ensure that the primary electron beam is deflectable perpendicular to the optical axis 20 of the SEM 100 in the object plane 16 such that the surface of the object 15 arranged in the object plane 16 can be scanned by different deflections of the primary electron beam. In the process, the electrons of the primary electron beam interact with the object 15. As a consequence of the interaction, electrons in particular are emitted by the object 15 (so-called secondary electrons), and electrons of the primary electron beam are backscattered (so-called backscattered electrons). The secondary electrons and the backscattered electrons are detected and used for image generation. An image representation of the object 15 to be examined is thus obtained. Furthermore, interaction radiation, for example x-ray radiation or cathodoluminescence, is generated during the interaction, and the interaction radiation is detected and subsequently evaluated in order to analyse the object 15.

For the detection of the aforementioned interaction particles and/or aforementioned interaction radiation, a first detector unit 14 is arranged in the sample chamber 13, for example. In addition or as an alternative thereto, for example a second detector unit 8 for detecting the aforementioned interaction particles is arranged in the beam guiding tube 21 in the region between the first deflection unit 9 and the second condenser lens 6.

In the embodiment of the SEM 100 illustrated in FIG. 1, a pressure stage aperture mount 17 is provided and can be arranged on the pole piece 22 of the objective lens 10, the pole piece projecting into the sample chamber 13. The pressure stage aperture mount 17 includes a pressure stage aperture unit with an aperture 18. Further pressure stage aperture units can be arranged, for example, within the beam guiding tube 21 of the SEM 100. The further pressure stage aperture units are not illustrated in FIG. 1. FIG. 1 does not illustrate vacuum pumps either, the latter being desired for generating and maintaining the vacuum desired for operating the SEM 100 within the beam guiding tube 21 and the sample chamber 13.

The pressure stage aperture mount 17 is not mandatory if the SEM 100 is intended to be operated under high vacuum in the sample chamber 13, and so the pressure stage aperture mount 17 can therefore be removed from the pole piece 22 of the objective lens 10. By contrast, if the SEM 100 is intended to be operated at relatively high pressure in the sample chamber 13 (pressures in the range of approximately 1 to 3000 Pa), the pressure stage aperture mount 17 should be mounted on the pole piece 22 of the objective lens 10 so that a sufficiently good vacuum can be maintained within the beam guiding tube 21 by differential pumping, despite the higher pressure in the sample chamber 13. In the event of a mounted pressure stage aperture mount 17, the edge of the aperture 18 within the pressure stage aperture mount 17 leads to a trimming of the image field which can be scanned in the object plane 16.

In particular, the first detector unit 14, the second detector unit 8, the first deflection unit 9 and the second deflection unit 12 are connected to a control device 123 having a monitor 124. The control device 123 processes detection signals generated by the first detector unit 14 and the second detector unit 8 and displays the signals in the form of images on the monitor 124. The control device 123 furthermore includes a database 126, in which data are stored and from which data are read out. Moreover, the control device 123 is connected to further units of the SEM 100. This is not illustrated in detail in FIG. 1.

The control device 123 of the SEM 100 includes a processor 127. A computer program product having a program code which, when executed, carries out a method for operating the SEM 100 is loaded into the processor 127. This is explained in more detail elsewhere herein.

In the SEM 100, it is possible to adjust a distance A using the control device 123 of the SEM 100. The distance A is given either (a) by an object distance between an outer boundary of the objective lens 10 of the SEM 100 and the object 15 or (b) by a focal plane distance between the outer boundary of the objective lens 10 of the SEM 100 and a focal plane of the objective lens 10. For example, the focal plane is in the object plane 16. The aforementioned distance A according to case (a) or case (b) is also referred to as working distance. For example, the distance A in case (a) is adjusted by moving the object stage 19 and/or moving the objective lens 10 using a movement device 25. In particular, the distance A in case (b) is adjusted by varying an excitation of the objective lens 10 along the optical axis 20 of the SEM 100.

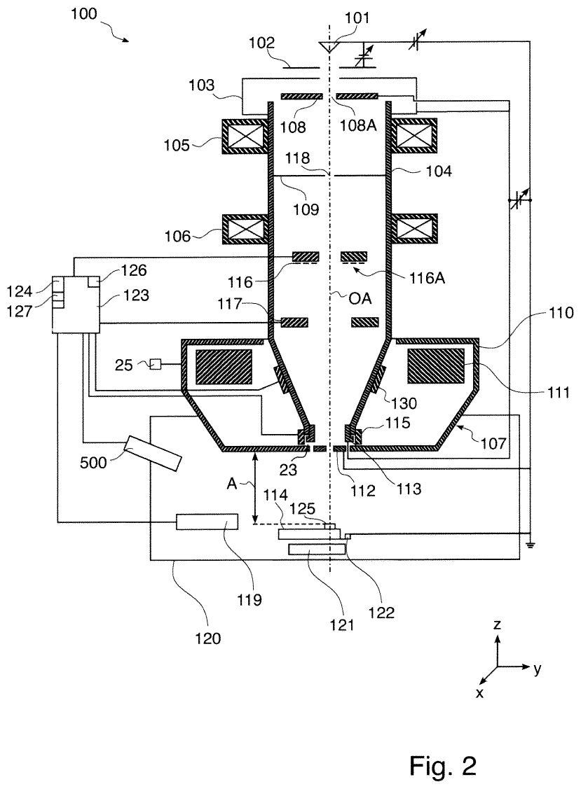

FIG. 2 shows a schematic illustration of a further SEM 100. The further SEM 100 includes a first beam generator in the form of an electron source 101, which is embodied as a cathode. Furthermore, the further SEM 100 is provided with an extraction electrode 102 and with an anode 103, which is placed onto one end of a beam guiding tube 104 of the further SEM 100. By way of example, the electron source 101 is embodied as a thermal field emitter. However, the invention is not restricted to such an electron source 101. Rather, any electron source suitable for the invention can be used.

Electrons that emerge from the electron source 101 form a primary electron beam. The electrons are accelerated to anode potential owing to a potential difference between the electron source 101 and the anode 103. In the embodiment illustrated in FIG. 2, the anode potential is 100 V to 35 kV, for example 5 kV to 15 kV, in particular 8 kV, relative to an earth potential of a housing of a sample chamber 120. However, the anode potential could alternatively also be at earth potential.

Two condenser lenses, specifically a first condenser lens 105 and a second condenser lens 106, are arranged on the beam guiding tube 104. As viewed in the direction of a first objective lens 107 proceeding from the electron source 101, the first condenser lens 105 is arranged first in this case, followed by the second condenser lens 106. Explicit reference is made to the fact that further embodiments of the further SEM 100 may include only a single condenser lens. A first aperture unit 108 is arranged between the anode 103 and the first condenser lens 105. Together with the anode 103 and the beam guiding tube 104, the first aperture unit 108 is at a high-voltage potential, specifically the potential of the anode 103, or connected to earth. The first aperture unit 108 includes numerous first apertures 108A, one of which is illustrated in FIG. 2. For example, two first apertures 108A are present. Each one of the numerous first apertures 108A has a different aperture diameter. Using an adjusting mechanism (not illustrated), it is possible to adjust a desired first aperture 108A onto an optical axis OA of the further SEM 100. Explicit reference is made to the fact that, in further embodiments, the first aperture unit 108 can be provided only with a single first aperture 108A. An adjusting mechanism may not be provided in the further embodiments. The first aperture unit 108 is then stationary. A stationary second aperture unit 109 is arranged between the first condenser lens 105 and the second condenser lens 106. As an alternative thereto, provision is made for the second aperture unit 109 to be movable.

The first objective lens 107 includes a pole piece 110, in which a drilled hole is formed. The beam guiding tube 104 is guided through the drilled hole. A coil 111 is arranged in the pole piece 110. Furthermore, the pole piece 110 includes a pole piece gap 23.

An electrostatic retardation device is arranged in a lower region of the beam guiding tube 104. The electrostatic retardation device includes a single electrode 112 and a tube electrode 113. The tube electrode 113 is arranged at an end of the beam guiding tube 104 that faces an object 125 arranged on a movable object holder 114.

Together with the beam guiding tube 104, the tube electrode 113 is at the potential of the anode 103, while the single electrode 112 and the object 125 are at a lower potential in relation to the potential of the anode 103. In the present case, the lower potential is the earth potential of the housing of the sample chamber 120. In this way, the electrons of the primary electron beam can be decelerated to a desired energy which is desired for examining the object 125.

The object 125 and the single electrode 112 may also be at different potentials and potentials that differ from earth. This makes it possible to adjust the location of the retardation of the primary electron beam in relation to the object 125. By way of example, if the retardation is carried out quite close to the object 125, imaging aberrations become smaller.

The further SEM 100 furthermore includes a deflection device having a first deflection unit 130 and having a second deflection unit 115. The first deflection unit 130 is arranged on the source side within the first objective lens 107. By contrast, the second deflection unit 115 is arranged on the object side on the beam guiding tube 104 within the first objective lens 107. Furthermore, the second deflection unit 115 is arranged in the region of the pole piece gap 23 and/or at the pole piece gap 23 of the pole piece 110. The first deflection unit 130 and the second deflection unit 115 are crossed beam deflection units. In other words, both the first deflection unit 130 and the second deflection unit 115 are embodied in such a way that the first deflection unit 130 and the second deflection unit 115 deflect the primary electron beam in two directions which are not parallel to each other and are oriented perpendicular to the direction of the optical axis OA of the further SEM 100. For example, the first deflection unit 130 and/or the second deflection unit 115 are/is embodied as (a) magnetic deflection unit(s). In particular, the first deflection unit 130 and/or the second deflection unit 115 accordingly each include(s), for example, four air coils arranged around the optical axis OA of the further SEM 100. However, the invention is not restricted to the aforementioned number of air coils. Rather, any number of air coils which is suitable for the invention can be used. In addition or as an alternative to that, provision is made for the first deflection unit 130 and/or the second deflection unit 115 to be embodied as (an) electrostatic deflection unit(s). In particular, the first deflection unit 130 and/or the second deflection unit 115 accordingly each include(s), for example, four electrodes which are arranged around the optical axis OA of the further SEM 100 and to which different electrostatic potentials can be applied. However, the invention is not restricted to the aforementioned number of electrodes. Rather, any number of electrodes that is suitable for the invention can be used. Using the first deflection unit 130 and the second deflection unit 115, the primary electron beam is deflected and can be scanned over the object 125. In the process, the electrons of the primary electron beam interact with the object 125. The interaction gives rise to interaction particles, which are detected. In particular, interaction particles are electrons that are emitted from the surface of the object 125—so-called secondary electrons—or electrons of the primary electron beam that are backscattered—so-called backscattered electrons.

A detector arrangement that includes a first detector 116 and a second detector 117 is arranged in the beam guiding tube 104 for the purpose of detecting the secondary electrons and/or the backscattered electrons. In this case, the first detector 116 is arranged on the source side along the optical axis OA in the beam guiding tube 104, while the second detector 117 is arranged on the object side along the optical axis OA in the beam guiding tube 104. The first detector 116 and the second detector 117 are arranged offset from one another in the direction of the optical axis OA of the further SEM 100. Both the first detector 116 and the second detector 117 have a respective through opening, through which the primary electron beam can pass. The first detector 116 and the second detector 117 are approximately at the potential of the anode 103 and beam guiding tube 104. The optical axis OA of the further SEM 100 runs through the respective through openings.

The second detector 117 is used mainly to detect secondary electrons. Upon emergence from the object 125, the secondary electrons initially have a low kinetic energy and random directions of movement. The secondary electrons are accelerated in the direction of the first objective lens 107 by the strong extraction field that emanates from the tube electrode 113. The secondary electrons enter the first objective lens 107 approximately in a parallel fashion. The beam diameter of the beam of the secondary electrons remains small even in the first objective lens 107. The first objective lens 107 then has a strong effect on the secondary electrons and generates a comparatively short focus of the secondary electrons with sufficiently steep angles to the optical axis OA, and so the secondary electrons diverge significantly from one another downstream of the focus and are incident on the active area of the second detector 117. By contrast, only a small proportion of electrons backscattered at the object 125—i.e. backscattered electrons with a relatively high kinetic energy in comparison with the secondary electrons upon emergence from the object 125—are detected by the second detector 117. The high kinetic energy and the angles of the backscattered electrons to the optical axis OA upon emergence from the object 125 have the effect that a beam waist, i.e. a beam region of minimal diameter, of the backscattered electrons lies in the vicinity of the second detector 117. A large portion of the backscattered electrons pass through the through opening of the second detector 117. Therefore, the first detector 116 substantially serves to detect the backscattered electrons.

In a further embodiment of the further SEM 100, the first detector 116 can additionally be embodied with an opposing field grid 116A. The opposing field grid 116A is arranged on that side of the first detector 116 which is directed towards the object 125. With respect to the potential of the beam guiding tube 104, the opposing field grid 116A has a negative potential such that only backscattered electrons with a high kinetic energy pass through the opposing field grid 116A to the first detector 116. Additionally or alternatively, the second detector 117 includes a further opposing field grid, which has an analogous embodiment to the aforementioned opposing field grid 116A of the first detector 116 and has an analogous function.

Furthermore, in the sample chamber 120 the further SEM 100 includes a chamber detector 119, for example an Everhart-Thornley detector or an ion detector, which has a metal-coated detection surface that blocks light.

The detection signals generated by the first detector 116, the second detector 117 and the chamber detector 119 are used to generate an image or images of the surface of the object 125.

Reference is explicitly made to the fact that the apertures of the first aperture unit 108 and 10) second aperture unit 109, as well as the through openings of the first detector 116 and of the second detector 117, are illustrated in exaggerated fashion. The through openings of the first detector 116 and of the second detector 117 have an extent perpendicular to the optical axis OA in the range of 0.5 mm to 5 mm. For example, the openings are circular and have a diameter in the range of 1 mm to 3 mm perpendicular to the optical axis OA.

The second aperture unit 109 is configured as a pinhole aperture unit in the embodiment illustrated in FIG. 2 and is provided with a second aperture 118 for the passage of the primary electron beam, which second aperture has an extent in the range of 5 μm to 500 μm, for example 35 μm. As an alternative thereto, in a further embodiment, provision is made for the second aperture unit 109 to be provided with a plurality of apertures, which can be displaced mechanically with respect to the primary electron beam or which can be reached by the primary electron beam using electrical and/or magnetic deflection elements. The second aperture unit 109 is embodied as a pressure stage aperture unit. This separates a first region, in which the electron source 101 is arranged and in which there is an ultra-high vacuum (10⁻⁷ hPa to 10⁻¹² hPa), from a second region, which has a high vacuum (10⁻³ hPa to 10⁻⁷ hPa). The second region is the intermediate pressure region of the beam guiding tube 104 leading to the sample chamber 120.

The sample chamber 120 is under vacuum. In order to generate the vacuum, a pump (not illustrated) is arranged on the sample chamber 120. In the embodiment illustrated in FIG. 2, the sample chamber 120 is operated in a first pressure range or in a second pressure range. The first pressure range includes only pressures of less than or equal to 10⁻³ hPa, and the second pressure range includes only pressures of greater than 10⁻³ hPa. The sample chamber 120 is vacuum-sealed in order to ensure the first pressure range and the second pressure range.

The object holder 114 is arranged on an object stage 122. The object stage 122 is movable in three directions arranged perpendicular to one another, specifically in an x-direction (first stage axis), in a y-direction (second stage axis) and in a z-direction (third stage axis). Moreover, the object stage 122 can be rotated about two axes of rotation (axes of rotation of the stage) which are arranged perpendicular to one another. The invention is not restricted to the object stage 122 described above. Rather, the object stage 122 can have further translation axes and axes of rotation, along which or about which the object stage 122 can move.

The further SEM 100 furthermore includes a third detector 121 arranged in the sample chamber 120. More precisely, the third detector 121 is arranged downstream of the object stage 122, as viewed from the electron source 101 along the optical axis OA. The object stage 122, and hence the object holder 114, can be rotated in such a way that the primary electron beam can radiate through the object 125 arranged on the object holder 114. When the primary electron beam passes through the object 125 to be examined, the electrons of the primary electron beam interact with the material of the object 125 to be examined. The electrons passing through the object 125 to be examined are detected by the third detector 121.

Arranged on the sample chamber 120 is a radiation detector 500, which is used to detect interaction radiation, for example x-ray radiation and/or cathodoluminescence, generated when the primary electron beam is incident on the object 125. The radiation detector 500, the first detector 116, the second detector 117 and the chamber detector 119 are connected to a control device 123 that includes a monitor 124. The third detector 121 is also connected to the control device 123. This is not illustrated for reasons of clarity. The control device 123 processes detection signals generated by the first detector 116, the second detector 117, the chamber detector 119, the third detector 121 and/or the radiation detector 500 and displays the detection signals in the form of images on the monitor 124.

The control device 123 furthermore includes a database 126, in which data are stored and from which data are read out. Further, the control device 123 is connected to the deflection device in the form of the first deflection unit 130 and the second deflection unit 115. Moreover, the control device 123 is connected to further units of the further SEM 100. This is not illustrated in more detail for reasons of clarity.

The control device 123 of the further SEM 100 includes a processor 127. A computer program product having a program code which, when executed, carries out a method for operating the further SEM 100 is loaded into the processor 127. This is explained in more detail elsewhere herein.

In the further SEM 100, it is possible to adjust a distance A using the control device 123 of the further SEM 100. The distance A is given either (a) by an object distance between an outer boundary of the first objective lens 107 of the further SEM 100 and the object 125 or (b) by a focal plane distance between the outer boundary of the first objective lens 107 of the further SEM 100 and a focal plane of the first objective lens 107. The aforementioned distance A according to case (a) or case (b) is also referred to as working distance. For example, the distance A in case (a) is adjusted by moving the object stage 122 and/or moving the first objective lens 107 using a movement device 25. For example, the distance A in case (b) is adjusted by varying an excitation of the first objective lens 107 along the optical axis OA of the further SEM 100.

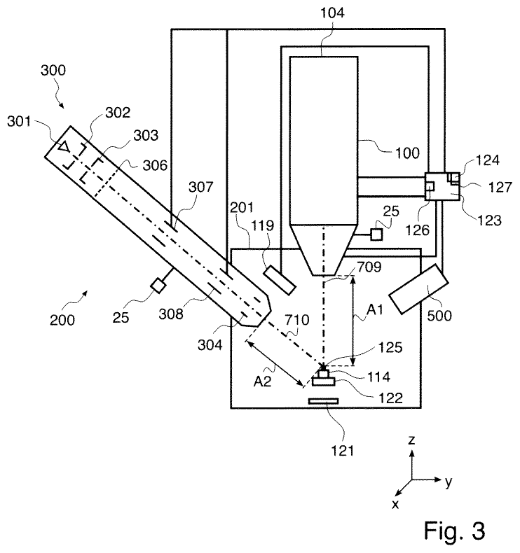

FIG. 3 shows a particle beam apparatus in the form of a combination apparatus 200. The combination apparatus 200 includes two particle beam columns. Firstly, the combination apparatus 200 is provided with the further SEM 100, as illustrated in FIG. 2, albeit without the sample chamber 120. Rather, the further SEM 100 is arranged on a sample chamber 201. The sample chamber 201 is under vacuum. In order to generate the vacuum, a pump (not illustrated) is arranged on the sample chamber 201. In the embodiment illustrated in FIG. 3, the sample chamber 201 is operated in a first pressure range or in a second pressure range. The first pressure range includes only pressures of less than or equal to 10⁻³ hPa, and the second pressure range includes only pressures of greater than 10⁻³ hPa. The sample chamber 201 is vacuum-sealed in order to ensure the first pressure range and the second pressure range.

Arranged in the sample chamber 201 is the chamber detector 119, which for example is embodied as an Everhart-Thornley detector or as an ion detector and has a metal-coated detection surface that blocks light. Furthermore, the third detector 121 is arranged in the sample chamber 201.

The further SEM 100 serves to generate a first particle beam, specifically the primary electron beam described further above, and includes the optical axis discussed elsewhere herein, which is provided with the reference sign 709 in FIG. 3 and is also referred to as first beam axis below. Secondly, the combination apparatus 200 is provided with an ion beam apparatus 300 likewise arranged on the sample chamber 201. The ion beam apparatus 300 likewise has an optical axis, which is provided with the reference sign 710 in FIG. 3 and is also referred to as second beam axis below.

The further SEM 100 is arranged vertically in relation to the sample chamber 201. By contrast, the ion beam apparatus 300 is arranged in a manner inclined by an angle of approximately 0° to 90° in relation to the SEM 100. An arrangement of approximately 50° is illustrated by way of example in FIG. 3. The ion beam apparatus 300 includes a second beam generator in the form of an ion beam generator 301. Ions that form a second particle beam in the form of an ion beam are generated by the ion beam generator 301. The ions are accelerated using an extraction electrode 302 at a predefinable potential. The second particle beam then passes through an ion optical unit of the ion beam apparatus 300, the ion optical unit including a condenser lens 303 and a second objective lens 304. The second objective lens 304 ultimately generates an ion probe, which is focused on the object 125 arranged on an object holder 114. The object holder 114 is arranged on an object stage 122.

An adjustable or selectable aperture unit 306 and a deflection device are arranged above the second objective lens 304 (i.e. in the direction of the ion beam generator 301). The deflection device includes a first deflection unit 307 and a second deflection unit 308. The first deflection unit 307 is arranged on the source side within the second objective lens 304. By contrast, the second deflection unit 308 is arranged on the object side within the second objective lens 304. The first deflection unit 307 and the second deflection unit 308 are crossed beam deflection units. In other words, both the first deflection unit 307 and the second deflection unit 308 are embodied in such a way that the first deflection unit 307 and the second deflection unit 308 deflect the ion beam in two directions which are not parallel to each other and are oriented perpendicular to the direction of the optical axis in the form of the second beam axis 710 of the ion beam apparatus 300. For example, the first deflection unit 307 and/or the second deflection unit 308 are/is embodied as (a) magnetic deflection unit(s). In particular, the first deflection unit 307 and/or the second deflection unit 308 accordingly each include(s), for example, four air coils that are arranged around the optical axis in the form of the second beam axis 710 of the ion beam apparatus 300. However, the invention is not restricted to the aforementioned number of air coils. Rather, any number of air coils which is suitable for the invention can be used. In addition or as an alternative to that, provision is made for the first deflection unit 307 and/or the second deflection unit 308 to be embodied as (an) electrostatic deflection unit(s). In particular, the first deflection unit 307 and/or the second deflection unit 308 accordingly each include(s), for example, four electrodes which are arranged around the optical axis in the form of the second beam axis 710 of the ion beam apparatus 300 and to which different electrostatic potentials can be applied. However, the invention is not restricted to the aforementioned number of electrodes. Rather, any number of electrodes that is suitable for the invention can be used.

Using the first deflection unit 307 and the second deflection unit 308, the ion beam is deflected and can be scanned over the object 125.

As explained above, the object holder 114 is arranged on the object stage 122. In the embodiment shown in FIG. 3, too, the object stage 122 is movable in three directions arranged perpendicular to one another, specifically in an x-direction (first stage axis), in a y-direction (second stage axis) and in a z-direction (third stage axis). Moreover, the object stage 122 can be rotated about two axes of rotation (axes of rotation of the stage) which are arranged perpendicular to one another.

The distances illustrated in FIG. 3 between the individual units of the combination apparatus 200 are illustrated in exaggerated fashion in order to better illustrate the individual units of the combination apparatus 200.

A radiation detector 500 used to detect interaction radiation, for example x-ray radiation and/or cathodoluminescence, is arranged on the sample chamber 201. The radiation detector 500 is connected to a control device 123 having a monitor 124.

The control device 123 processes detection signals generated by the first detector 116 (not illustrated in FIG. 3), the second detector 117 (not illustrated in FIG. 3), the chamber detector 119, the third detector 121 and/or the radiation detector 500 and displays the detection signals in the form of images on the monitor 124.

The control device 123 furthermore includes a database 126, in which data are stored and from which data are read out. Furthermore, the control device 123 is connected to the deflection device in the form of the first deflection unit 130 (not illustrated in FIG. 3) and the second deflection unit 115 (not illustrated in FIG. 3) for the primary electron beam of the further SEM 100 and to the deflection device in the form of the first deflection unit 307 and the second deflection unit 308 for the ion beam of the ion beam apparatus 300.

The control device 123 of the combination apparatus 200 includes a processor 127. A computer program product having a program code which, when executed, carries out a method for operating the combination apparatus 200 is loaded into the processor 127. This is explained in more detail further below.

In the combination apparatus 200, too, it is possible to adjust working distances. It is possible in the further SEM 100, for example, to adjust a distance A1 using the control device 123. The distance A1 is given either (a) by an object distance between an outer boundary of the first objective lens 107 of the further SEM 100 and the object 125 or (b) by a focal plane distance between the outer boundary of the first objective lens 107 of the further SEM 100 and a focal plane of the first objective lens 107. The aforementioned distance A1 according to case (a) or case (b) is also referred to as working distance. For example, the distance A1 in case (a) is adjusted by moving the object stage 122 and/or moving the first objective lens 107 using the movement device 25. For example, the distance A1 in case (b) is adjusted by varying an excitation of the first objective lens 107 along the first beam axis 709 of the further SEM 100. It is furthermore possible to adjust a distance A2 using the control device 123. The distance A2 is given either (a) by an object distance between an outer boundary of the second objective lens 304 of the ion beam apparatus 300 and the object 125 or (b) by a focal plane distance between the outer boundary of the second objective lens 304 of the ion beam apparatus 300 and a focal plane of the second objective lens 304. The aforementioned distance A2 according to case (a) or case (b) is also referred to as working distance. For example, the distance A2 in case (a) is adjusted by moving the object stage 122 and/or moving the second objective lens 304 using a movement device 25. For example, the distance A2 in case (b) is adjusted by varying an excitation of the second objective lens 304 along the second beam axis 710 of the ion beam apparatus 300.

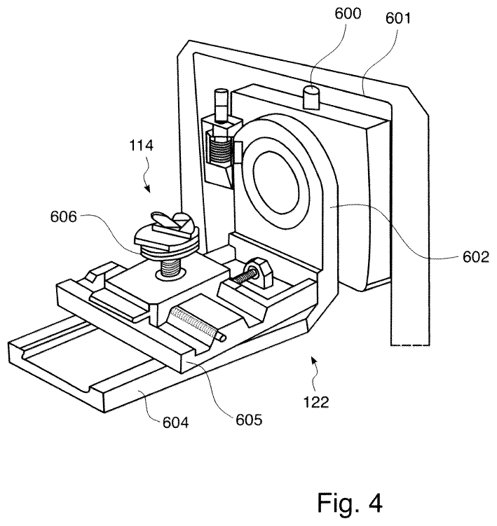

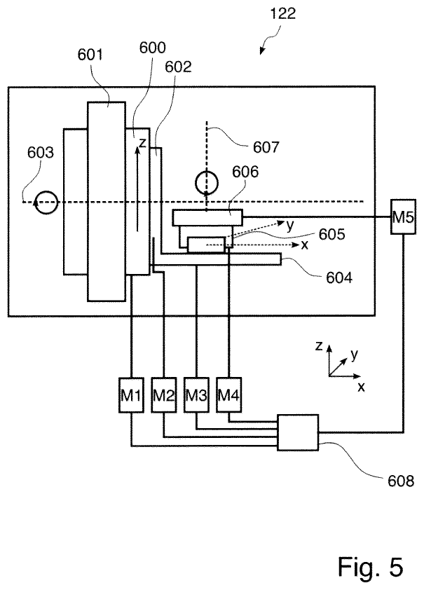

The object stage 122 of the further SEM 100 as per FIG. 2 and of the combination apparatus 200 as per FIG. 3 are discussed in more detail below. The object stage 122 is embodied as a movable object stage, which is illustrated schematically in FIGS. 4 and 5. The same applies to the object stage 19 of the SEM 100 as per FIG. 1.

Reference is made to the fact that the invention is not restricted to the object stage 122 described here. Rather, the invention can include any movable object stage suitable for the invention.

The object holder 114 is arranged on the object stage 122. The object stage 122 includes movement elements that ensure a movement of the object stage 122 in such a way that a region of interest on the object 125 can be examined, for example using a particle beam. The movement elements are illustrated schematically in FIGS. 4 and 5 and are explained below.

The object stage 122 includes a first movement element 600 arranged for example on a housing 601 of the sample chamber 120 or 201, in which the object stage 122 is arranged in turn. The first movement element 600 enables a movement of the object stage 122 along the z-axis (third stage axis). A second movement element 602 is also provided. The second movement element 602 enables a rotation of the object stage 122 about a first axis of rotation 603 of the stage, which is also referred to as a tilt axis. The second movement element 602 serves to tilt the object 125 about the first axis of rotation 603 of the stage, where the object 125 is arranged on the object holder 114.

In turn, a third movement element 604, which is embodied as a guide for a slide and ensures that the object stage 122 is movable in the x-direction (first stage axis), is arranged on the second movement element 602. The aforementioned slide is in turn a further movement element, specifically a fourth movement element 605. The fourth movement element 605 is embodied in such a way that the object stage 122 is movable in the y-direction (second stage axis). For this purpose, the fourth movement element 605 includes a guide in which a further slide is guided, the object holder 114 in turn being arranged on the latter. The object holder 114 is in turn embodied with a fifth movement element 606, which enables a rotation of the object holder 114 about a second axis of rotation 607 of the stage. The second axis of rotation 607 of the stage is oriented perpendicular to the first axis of rotation 603 of the stage.

On account of the above-described arrangement, the object stage 122 of the embodiment illustrated in FIG. 4 has the following kinematic chain: first movement element 600 (movement along the z-axis)—second movement element 602 (rotation about the first axis of rotation 603 of the stage)—third movement element 604 (movement along the x-axis)—fourth movement element 605 (movement along the y-axis)-fifth movement element 606 (rotation about the second axis of rotation 607 of the stage).

In a further embodiment (not illustrated), provision is made for further movement elements to be arranged on the object stage 122 such that movements along further translational axes and/or about further axes of rotation are made possible.

As is evident from FIG. 5, each of the aforementioned movement elements is connected to a drive unit in the form of a motor M1 to M5. In this regard, the first movement element 600 is connected to a first drive unit M1 and is driven owing to a driving force that is provided by the first drive unit M1. The second movement element 602 is connected to a second drive unit M2, which drives the second movement element 602. The third movement 30 element 604 is connected in turn to a third drive unit M3. The third drive unit M3 provides a driving force for driving the third movement element 604. The fourth movement element 605 is connected to a fourth drive unit M4, where the fourth drive unit M4 drives the fourth movement element 605. Furthermore, the fifth movement element 606 is connected to a fifth drive unit M5. The fifth drive unit M5 provides a driving force that drives the fifth movement element 606.

The aforementioned drive units M1 to M5 can be embodied as stepper motors, for example, and are controlled by a drive control unit 608 and are each supplied with a supply current by the drive control unit 608 (cf. FIG. 5). Explicit reference is made to the fact that the invention is not restricted to the movement using stepper motors. Rather, any drive units suitable for the invention, for example brushless motors or piezoactuators, can be used as drive units.

Embodiments of the method according to the system described herein are explained in more detail below in relation to the SEM 100 as per FIG. 1. The same applies to the further SEM 100 as per FIG. 2 and to the combination apparatus 200 as per FIG. 3.

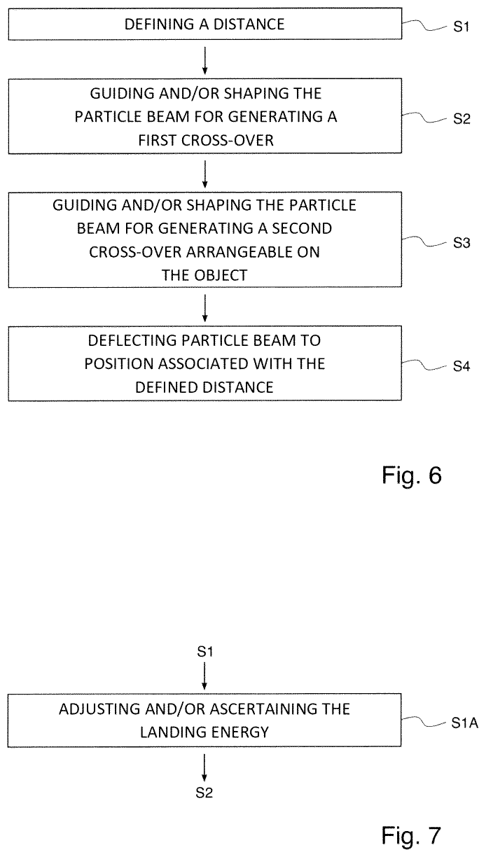

FIG. 6 shows one embodiment of the method according to the system described herein that is carried out by the SEM 100 as per FIG. 1. In the embodiment of the method according to the system described herein as per FIG. 6, method step S1 involves defining a distance A using the control device 123 of the SEM 100. The distance A is given either (a) by an object distance between the outer boundary of the objective lens 10 of the SEM 100 and the object 15 or (b) by a focal plane distance between the outer boundary of the objective lens 10 of the SEM 100 and a focal plane of the objective lens 10. The above-mentioned distance according to case (a) or case (b) is also referred to as working distance. For example, provision is made for defining the distance A (that is to say defining the working distance) according to case (a) to be effected by a relative movement of the object 15 with respect to the objective lens 10 (for example by a movement of the object 15 and/or by a movement of the objective lens 10) and/or by ascertaining the object distance. Ascertaining the object distance includes, for example, measuring the object distance and/or reading the object distance on a measuring device. In a further embodiment of the method according to the system described herein, provision is additionally or alternatively made for defining the distance A according to case (b) to be effected by controlling the objective lens 10 for positioning a focal plane of the objective lens 10 and/or by ascertaining the focal plane distance. Ascertaining the focal plane distance includes, for example, measuring the focal plane distance and/or reading the focal plane distance on the 30 measuring device. In yet another embodiment of the method according to the system described herein, provision is additionally or alternatively made for the distance A (i.e. the working distance) to be defined using at least one of the following method steps: (i) moving the object stage 19, on which the object 15 is arranged, along the optical axis 20 of the 35 SEM 100; (ii) moving the object stage 19, on which the object 15 is arranged, relative to the optical axis 20 of the SEM 100, the movement not being perpendicular to the optical axis 20; (iii) moving the objective lens 10 of the SEM 100 along the optical axis 20 of the SEM 100 using the movement device 25; and (iv) moving the objective lens 10 of the SEM 100 relative to the optical axis 20 using the movement device 25, the movement not being perpendicular to the optical axis 20.

In method step S2, provision is made in the embodiment of the method according to the system described herein as per FIG. 6 for the primary electron beam to be guided and/or shaped by the first condenser lens 5 and/or by the second condenser lens 6 of the SEM 100 in such a way that a first cross-over CO1 is generated in the objective lens 10. To generate the first cross-over CO1, the first condenser lens 5 and the second condenser lens 6 are controlled with a predefinable value of a condenser lens current using the control device 123.

In method step S3, provision is made in the embodiment of the method according to the system described herein as per FIG. 6 for the primary electron beam to be guided and/or shaped using the objective lens 10 in such a way that a second cross-over CO2 of the primary electron beam, the second cross-over being arrangeable on the object 15, is generated. For this purpose, the objective lens 10 is controlled with a predefinable value of an objective lens current using the control device 123.

In method step S4, provision is made in the embodiment of the method according to the system described herein as per FIG. 6 for the particle beam in the form of the primary electron beam to be deflected to a position KP along the optical axis 20 of the SEM 100 depending on the defined distance A (that is to say the defined working distance) using the deflection device in the form of the first deflection unit 9 and the second deflection unit 12. Accordingly, the abovementioned position KP is associated with the defined distance A. In other words, the primary electron beam is guided by the first deflection unit 9 and the second deflection unit 12 to the position KP along the optical axis 20 of the SEM 100 depending on the defined working distance A.

The abovementioned position KP of the primary electron beam along the optical axis 20 of the SEM 100 is, for example, the tilting point of the primary electron beam, explained further above. Furthermore, the abovementioned position KP of the primary electron beam along the optical axis 20 is arranged within the second deflection unit 12. The deflection device in the form of the first deflection unit 9 and the second deflection unit 12 is controlled with control signals using the control device 123 of the SEM 100 in such a way that aberrations generated by the objective lens 10 are reduced or avoided. With regard to reducing the aberrations, reference is made to the explanations provided elsewhere herein, which are applicable, mutatis mutandis, here as well. For example, the deflection device is controlled using the control device 123 of the SEM 100 in such a way that the aberrations generated by the objective lens 10 are minimal.

In the system described herein, therefore, aberrations of the objective lens 10 are reduced or avoided. Accordingly, it is possible to attain a large image field which has smaller aberrations and/or no aberrations in comparison with the prior art. Consequently, on account of the system described herein, in the case of different operating modes of the SEM 100, it is always possible to attain such a large image field of the SEM 100 that navigation of the object 15 and/or some other assembly of the SEM 100 with respect to the object 15 in the sample chamber 13 of the SEM 100 with few errors is made possible.

For example, provision is made for the first cross-over CO1 to be arranged in the region of the pole piece gap 23. In particular, provision is made for the first cross-over CO1 and/or the second deflection unit 12 to be arranged in the region of the pole piece gap 23.

At the abovementioned position KP along the optical axis 20 of the SEM 100, for example, a central path of the primary electron beam has an axial distance perpendicular to the optical axis 20 of the SEM 100. With regard to the definition of the central path, reference is made to the explanations elsewhere herein, which are applicable here as well. At the defined distance A (i.e. the defined working distance), in the embodiment of the method according to the system described herein in connection with FIG. 6, the axial distance of the central path of the primary electron beam at the position KP along the optical axis 20 is smaller than all further axial distances of the central path of the primary electron beam perpendicular to the optical axis 20, where, for the defined distance A according to case (a), the further axial distances are arranged between a centre of the second deflection unit 12 and the object 15, and where, for the defined distance A according to case (b), the further axial distances are arranged between the centre of the second deflection unit 12 and the focal plane of the objective lens 10.

In a further embodiment of the method according to the system described herein as per FIG. 6, provision is made, in method step S4, for the first deflection unit 9 to be controlled with a first control signal using the control device 123. Furthermore, the second deflection unit 12 is controlled with a second control signal using the control device 123. The position KP of the primary electron beam associated with the defined distance is determined by the ratio of the first control signal to the second control signal. In other words, the position KP associated with the defined distance is dependent on the ratio of the first control signal to the second control signal.

FIG. 7 is a further embodiment of the method according to the system described herein. The embodiment in FIG. 7 is based on the embodiment in FIG. 6, and so firstly reference is made to the explanations further above, which are applicable here as well. In contrast to the embodiment in FIG. 6, the embodiment in FIG. 7 includes a further method step, specifically method step S1A, which is carried out between method steps S1 and S2, for example. In method step S1A, the landing energy with which the electrons of the primary electron beam are incident on the object 15 is adjusted and/or ascertained using the control device 123. For example, ascertaining the landing energy includes measuring the landing energy and/or reading the landing energy from a landing energy measuring device. The predefinable value of the condenser lens current in method step S2 is selected depending on the landing energy. Furthermore, the predefinable value of the objective lens current is likewise selected depending on the landing energy. Accordingly, the first cross-over CO1 in the embodiment of FIG. 7 is also dependent on the landing energy of the electrons of the primary electron beam; the second cross-over CO2 always lies at the location of the object 15, independently of the landing energy of the electrons of the primary electron beam. For example, in the embodiment of the method according to the system described herein explained in connection with FIG. 7, a control device having an acceleration device and/or deceleration device for the electrons of the primary electron beam is used as the control device 123.

In one embodiment of the method according to the system described herein as per FIG. 6 or FIG. 7, in method step S1, provision is additionally or alternatively made for defining the distance to be effected by adjusting the predefinable value of the condenser lens current, where the predefinable value of the objective lens current is not changed. Accordingly, in the embodiment of the method according to the system described herein in connection with FIG. 6 or FIG. 7, adjusting the working distance is effected exclusively by the first condenser lens 5 and/or by the second condenser lens 6. The objective lens current is kept constant. In other words, the objective lens current is thus not changed.

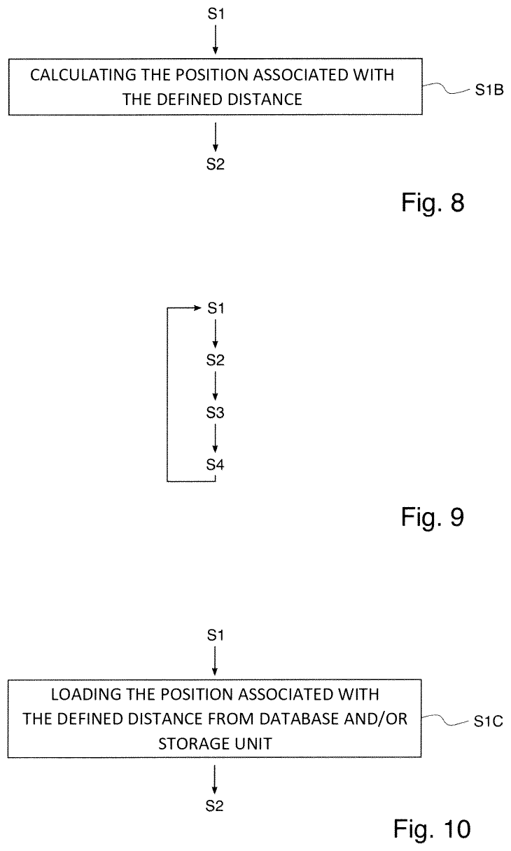

FIG. 8 shows a further embodiment of the method according to the system described herein. The embodiment of the method according to the system described herein as per FIG. 8 is based on the embodiment of the method according to the system described herein as per FIG. 6. Therefore, reference is made to the explanations given above, which are applicable here as well. In contrast to the embodiment of the method according to the system described herein as per FIG. 6, the embodiment of the method according to the system described herein as per FIG. 8 includes a further method step between method step S1 and method step S2, specifically method step S1B. In method step S1B, provision is made for the position KP of the primary electron beam along the optical axis 20 of the SEM 100, associated with the defined distance A (i.e. with the defined working distance), to be calculated using the control device 123. With regard to the calculation, reference is made to the explanations further above, which are applicable here as well. In method step S4, the primary electron beam is then deflected using the deflection device in the form of the first deflection unit 9 and the second deflection unit 12 in such a way that the primary electron beam is guided to the calculated position KP. In addition or as an alternative thereto, provision is made for the position KP associated with the distance A to be stored in the database 126 and/or the storage unit.

FIG. 9 shows a further embodiment of the method according to the system described herein. The embodiment of the method according to the system described herein as per FIG. 9 is based on the embodiment of the method according to the system described herein as per FIG. 6. Therefore, reference is made to the explanations given above, which are applicable here as well. In contrast to the embodiment of the method according to the system described herein as per FIG. 6, after method steps S1 to S4 have been carried out, method steps S1 to S4 are carried out repeatedly in succession. For example, after method steps S1 to S4 have been carried out, firstly method step S1, then method step S2, then method step S3 and then method step S4 are carried out. This therefore involves repeatedly defining the distance A, repeatedly guiding and/or shaping the primary electron beam using the first condenser lens 5 and/or using the second condenser lens 6 to generate a further first cross-over CO1, repeatedly guiding and/or shaping the primary electron beam using the objective lens 10 to generate a further second cross-over CO2, and repeatedly deflecting the primary electron beam to the position KP associated with the correspondingly defined distance A.

In the embodiment of the method according to the system described herein as per FIG. 9, provision is made for the associated position KP of the primary electron beam along the optical axis 20 of the SEM 100 to also change when the defined distance A (i.e. the defined working distance A) changes. Thus, in the embodiment of the method according to the system described herein corresponding to FIG. 9, the defined distance A is a first distance, the associated position KP of the primary electron beam along the optical axis 20 is a first associated position, the object distance is a first object distance, and the focal plane distance is a first focal plane distance. Repeating method step S1 involves defining a second distance using the control device 123 of the SEM 100. However, the defined second distance A is greater or less than the defined first distance A. The second distance A is given either (c) by a second object distance between the outer boundary of the objective lens 10 of the SEM 100 and the object 15 or (d) by a second focal plane distance between the outer boundary of the objective lens 10 of the SEM 100 and the focal plane of the objective lens 10. For example, provision is made for defining the second distance A (i.e. defining the second working distance A) according to case (c) to be effected by a relative movement of the object 15 with respect to the objective lens 10 and/or by ascertaining the object distance. Ascertaining the object distance includes, for example, measuring the object distance and/or reading the object distance on a measuring device. In yet another embodiment of the method according to the system described herein, provision is additionally or alternatively made for defining the second distance A according to case (d) to be effected by controlling the objective lens 10 for positioning a focal plane of the objective lens 10 and/or by ascertaining the focal plane distance. Ascertaining the focal plane distance includes, for example, measuring the focal plane distance and/or reading the focal plane distance on the measuring device. In yet another embodiment of the method according to the system described herein, provision is additionally or alternatively made for the second distance A to be defined using at least one of the following method steps: (i) moving the object stage 19, on which the object 15 is arranged, along the optical axis 20 of the SEM 100; (ii) moving the object stage 19, on which the object 15 is arranged, relative to the optical axis 20 of the SEM 100, the movement not being perpendicular to the optical axis 20; (iii) moving the objective lens 10 of the SEM 100 along the optical axis 20 of the SEM 100 using the movement device 25; and (iv) moving the objective lens 10 of the SEM 100 relative to the optical axis 20 using the movement device 25, the movement not being perpendicular to the optical axis 20.

Repeated method step S2 involves guiding and/or shaping the primary electron beam using the first condenser lens 5 and/or the second condenser lens 6 in such a way that a further first cross-over CO1 of the primary electron beam is generated in the objective lens 10. For this purpose, the first condenser lens 5 and/or the second condenser lens 6 are/is controlled with a further predefinable value of a condenser lens current using the control device 123. In repeated method step S3, the value of the objective lens current is not changed. Guiding and/or shaping the particle beam are/is effected using the objective lens 10 in such a way that a further second cross-over CO2 of the primary electron beam is generated at the object 15.

Repeated method step S4 involves deflecting the primary electron beam generated by the beam generator 1 of the SEM 100 to a second position KP along the optical axis 20 of the SEM 100 depending on the defined second distance (i.e. the defined second working distance) using the deflection device in the form of the first deflection unit 9 and the second deflection unit 12. Accordingly, the second position KP is associated with the defined second distance. In other words, the primary electron beam is guided by the deflection device to the second position KP along the optical axis 20 of the SEM 100 depending on the defined second working distance. The abovementioned second position KP of the primary electron beam along the optical axis 20 of the SEM 100 is, for example, a further tilting point of the primary electron beam. Furthermore, the abovementioned second position KP of the primary electron beam along the optical axis 20 is arranged within the second deflection unit 12. In the embodiment of the method according to the system described herein corresponding to FIG. 9, too, the deflection device is controlled with further control signals using the control device 123 of the SEM 100 in such a way that aberrations generated by the objective lens 10 are reduced or avoided. With regard to reducing the aberrations, reference is made to the explanations elsewhere herein, which are applicable, mutatis mutandis, here as well. Accordingly, in the embodiment corresponding to FIG. 9, too, it is possible to attain a large image field which has smaller aberrations and/or no aberrations in comparison with the prior art.

FIG. 10 shows a further embodiment of the method according to the system described herein. The embodiment of the method according to the system described herein as per FIG. 10 is based on the embodiment of the method according to the system described herein as per FIG. 6. Therefore, reference is made to the explanations given above, which are applicable here as well. In contrast to the embodiment of the method according to the system described herein as per FIG. 6, the embodiment of the method according to the system described herein as per FIG. 10 includes a further method step between method step S1 and method step S2, specifically method step S1C. In method step S1C, the position KP of the primary electron beam along the optical axis 20, associated with the 25 defined distance A (that is to say with the defined working distance), is loaded from the database 126 of the SEM 100 and/or from some other storage unit into the control device 123. In method step S4, the primary electron beam is then deflected using the deflection device in the form of the first deflection unit 9 and the second deflection unit 12 in such a way that the primary electron beam is guided to the loaded position KP. In other words, in the embodiment of the method according to the system described herein in connection 30 with FIG. 10, provision is made for the position KP of the tilting point depending on the working distance A to be stored in the database 126 and/or in the storage unit. If the working distance A has been defined, the associated position KP can be loaded from the database 126 and/or the storage unit. The primary electron beam is guided to the position KP 35 using the deflection device in the form of the first deflection unit 9 and the second deflection unit 12.

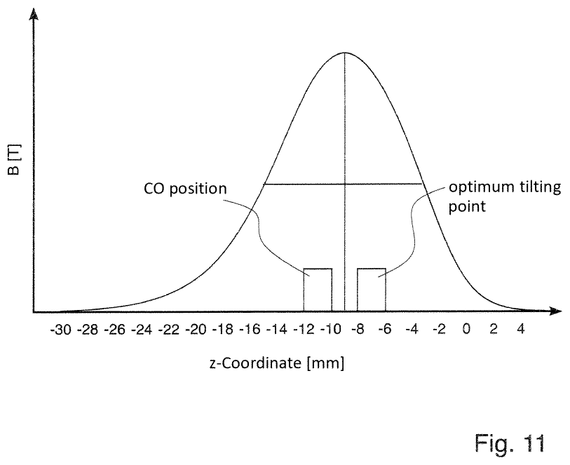

In a further embodiment of the method according to the system described herein, based on the embodiment of the method according to the system described herein as per FIG. 6, provision is made for the objective lens 10 excited with the objective lens current to generate a magnetic field. The magnetic field has a spatial distribution along the optical axis 20 of the SEM 100 in the region of the objective lens 10. The spatial distribution of the magnetic field has a full width at half maximum. The first cross-over CO1 of the primary electron beam generated in method step S2 lies within the full width at half maximum of the spatial distribution. FIG. 11 shows a schematic illustration of the magnetic field B of the objective lens 10 as a function of the z-coordinate. The advantageous positions of the generated first cross-over CO1 lie within the full width at half maximum of the spatial distribution of the magnetic field B. In FIG. 11, the advantageous positions of the first cross-over CO1 lie between the vertical lines of the region labelled “CO position”. An optimum tilting point KP lies within the full width at half maximum of the spatial distribution of the magnetic field B. In FIG. 11, the advantageous positions of the optimum tilting point KP lie between the vertical lines of the region labelled “optimum tilting point”. Considerations have revealed that when the first cross-over CO1 of the primary electron beam is arranged within the full width at half maximum of the spatial distribution of the magnetic field B of the objective lens 10, the method according to the system described herein is carried out particularly well.

In a further embodiment of the method according to the system described herein, based on the embodiment of the method according to the system described herein as per FIG. 6, provision is made, in method step S3, for the primary electron beam to be defocused by the objective lens 10 in such a way that a maximum deflection of the primary electron beam with respect to the optical axis 20 of the SEM 100 is attained.

All embodiments of the methods according to the invention described herein are not restricted to the explained order of the method steps. The invention also encompasses different orders of the method steps that are suitable for solving the problem within the meaning of the invention. Alternatively or additionally, in the methods according to the invention, provision is also made to carry out at least two method steps in parallel. Furthermore, the embodiments of the methods according to the invention above and below are not restricted to the complete scope of all the method steps mentioned above or further below. In particular, provision is made for individual or a plurality of the abovementioned or following method steps to be omitted in further embodiments.

The features of the invention disclosed in the present description, in the drawings and in the claims may be essential for the realization of the invention in the various embodiments thereof both individually and in arbitrary combinations. The invention is not restricted to the described embodiments. The invention can be varied within the scope of the claims and taking into account the knowledge of those skilled in the relevant art.

1. A method for operating a particle beam apparatus comprising:
defining a distance using a control device of the particle beam apparatus, wherein the distance is given either by an object distance between an outer boundary of an objective lens of the particle beam apparatus and the object or by a focal plane distance between the outer boundary of the objective lens of the particle beam apparatus and a focal plane of the objective lens;
guiding and/or shaping a particle beam that generates a first cross-over of the particle beam in the objective lens using a condenser lens arranged between a beam generator that generates the particle beam of the particle beam apparatus and the objective lens, wherein the condenser lens is controlled with a predefinable value of a condenser lens current using the control device;
guiding and/or shaping the particle beam that generates a second cross-over of the particle beam, the second cross-over being arrangeable on the object, using the objective lens, wherein the objective lens is controlled with a predefinable value of an objective lens current using the control device ; and
deflecting the particle beam to a position associated with the defined distance along an optical axis of the particle beam apparatus depending on the defined distance using a deflection device arranged within the objective lens and including at least one first deflection unit and at least one second deflection unit, wherein as viewed in the direction of the objective lens proceeding from the beam generator, firstly the first deflection unit and then the second deflection unit are arranged along the optical axis, wherein the position of the particle beam is arranged along the optical axis within the second deflection unit, and wherein the deflection device is controlled with control signals using the control device of the particle beam apparatus in such a way that aberrations generated by the objective lens are reduced.

2. The method according to claim 1, wherein the deflection device is controlled using the control device of the particle beam apparatus in such a way that the aberrations generated by the objective lens are minimal.

3. The method according to claim 1, wherein the deflection device is controlled using the control device as follows:
the first deflection unit is controlled with a first control signal using the control device, and
the second deflection unit is controlled with a second control signal using the control device, wherein the position of the particle beam associated with the defined distance is determined by the ratio of the first control signal to the second control signal.

4. The method according to claim 1, wherein a landing energy with which particles of the particle beam are incident on the object is adjusted and/or ascertained using the control device, wherein the predefinable value of the objective lens current and/or the condenser lens current are/is selected depending on the landing energy.

5. The method according to claim 4, wherein the control device includes an acceleration device and/or deceleration device for the particles of the particle beam.

6. The method according to claim 1, wherein defining the distance is effected by adjusting the predefinable value of the condenser lens current, wherein the predefinable value of the objective lens current is not changed.

7. The method according to claim 1, wherein:
defining the distance according to the object distance is effected by a relative movement of the object with respect to the objective lens and/or by ascertaining the object distance;
defining the distance according to the focal plane distance is effected by controlling the objective lens to position the focal plane of the objective lens and/or by ascertaining the focal plane distance.

8. The method according to claim 1, wherein defining the distance according to the object distance includes at least one of the following steps:
moving an object holder, on which the object is arranged, along the optical axis;
moving the object holder, on which the object is arranged, relative to the optical axis, wherein the movement is not perpendicular to the optical axis;
moving the objective lens of the particle beam apparatus along the optical axis using a movement device;
moving the objective lens of the particle beam apparatus relative to the optical axis using the movement device, wherein the movement is not perpendicular to the optical axis.

9. The method according to claim 1, wherein the position of the particle beam along the optical axis, associated with the defined distance, is calculated using the control device.

10. The method according to claim 1, wherein the defined distance is a first distance, wherein the position of the particle beam along the optical axis, associated with the first distance, is a first position, wherein the object distance is a first object distance, wherein the focal plane distance is a first focal plane distance, wherein the predefinable value of the condenser lens current is a first predefinable value of the condenser lens current, the method further comprising:
defining a second distance using the control device of the particle beam apparatus, wherein the second distance is given either by a second object distance between an outer boundary of the objective lens of the particle beam apparatus and the object, or by a second focal plane distance between the outer boundary of the objective lens of the particle beam apparatus and the focal plane of the objective lens;
guiding and/or shaping the particle beam that generates a further first cross-over of the particle beam in the objective lens using the condenser lens, wherein the condenser lens is controlled with a second predefinable value of the condenser lens current using the control device;
guiding and/or shaping the particle beam that generates a further second cross-over of the particle beam, the further second cross-over being arrangeable on the object, using the objective lens; and
deflecting the particle beam to a second position associated with the second defined distance along the optical axis of the particle beam apparatus depending on the second defined distance using the deflection device, wherein the second position of the particle beam is arranged along the optical axis within the second deflection unit, and wherein the deflection device is controlled with further control signals using the control device of the particle beam apparatus in such a way that the aberrations generated by the objective lens are reduced.

11. The method according to claim 1, wherein the position of the particle beam in the deflection device is loaded from a database and/or from a storage unit into the control device.

12. The method according to claim 1, wherein a central path of the particle beam at the position along the optical axis has an axial distance perpendicular to the optical axis of the particle beam apparatus, wherein, at the defined distance, the axial distance of the central path of the particle beam at the position along the optical axis is smaller than all further axial distances of the central path of the particle beam perpendicular to the optical axis of the particle beam apparatus, wherein, for the defined distance according to the object distance, the further axial distances are arranged between a centre of the second deflection unit of the deflection device and the object, and wherein, for the defined distance according to the focal plane distance, the further axial distances are arranged between the centre of the second deflection unit of the deflection device and the focal plane.

13. The method according to claim 1, wherein
the objective lens excited by the objective lens current generates a magnetic field,
the magnetic field has a spatial distribution along the optical axis of the particle beam apparatus in the region of the objective lens,
the spatial distribution of the magnetic field has a full width at half maximum, and wherein
the first cross-over of the particle beam lies within the full width at half maximum of the spatial distribution and/or wherein the associated position lies within the full width at half maximum of the spatial distribution.

14. The method according to claim 1, wherein an electrostatic and/or magnetic deflection device is used as the deflection device.

15. The method according to claim 1, wherein the particle beam is defocused by the objective lens in such a way that a maximum deflection of the particle beam with respect to the optical axis of the particle beam apparatus is attained.

16. A non-transitory computer readable storage medium containing executable code which is loadable into a processor and which, when executed, controls a particle beam apparatus by causing the particle beam apparatus to do the following:
define a distance using a control device of the particle beam apparatus, wherein the distance is given either by an object distance between an outer boundary of an objective lens of the particle beam apparatus and the object or by a focal plane distance between the outer boundary of the objective lens of the particle beam apparatus and a focal plane of the objective lens;
guide and/or shape a particle beam that generates a first cross-over of the particle beam in the objective lens using a condenser lens arranged between a beam generator that generates the particle beam of the particle beam apparatus and the objective lens, wherein the condenser lens is controlled with a predefinable value of a condenser lens current using the control device;
guide and/or shape the particle beam that generates a second cross-over of the particle beam, the second cross-over being arrangeable on the object, using the objective lens, wherein the objective lens is controlled with a predefinable value of an objective lens current using the control device; and
deflects the particle beam to a position associated with the defined distance along an optical axis of the particle beam apparatus depending on the defined distance using a deflection device arranged within the objective lens and including at least one first deflection unit and at least one second deflection unit, wherein as viewed in the direction of the objective lens proceeding from the beam generator, firstly the first deflection unit and then the second deflection unit are arranged along the optical axis, wherein the position of the particle beam is arranged along the optical axis within the second deflection unit, and wherein the deflection device is controlled with control signals using the control device of the particle beam apparatus in such a way that aberrations generated by the objective lens are reduced.

17. A particle beam apparatus for imaging, analysing and/or processing an object, comprising:
at least one beam generator that generates a particle beam having charged particles;
at least one condenser lens that guides and/or shapes the particle beam;
at least one objective lens that guides and/or shapes the particle beam on the object;
at least one deflection device having at least one first deflection unit and at least one second deflection unit, wherein as viewed from the beam generator in the direction of the objective lens, firstly the first deflection unit and then the second deflection unit are arranged, wherein both the first deflection unit and the second deflection unit are arranged in the objective lens; and
at least one control device having at least one processor coupled to a non-transitory computer readable storage medium containing executable code which is loadable into the processor and which, when executed, causes the particle beam apparatus to do the following:
define a distance using the at least one control device, wherein the distance is given either by an object distance between an outer boundary of the at least one objective lens and the object or by a focal plane distance between the outer boundary of the at least one objective lens and a focal plane of the at least one objective lens;
guide and/or shape the particle beam to generate a first cross-over of the particle beam in the at least one objective lens using the at least one condenser lens arranged between the at least one beam generator and the at least one objective lens, wherein the at least one condenser lens is controlled with a predefinable value of a condenser lens current using the at least one control device;
guide and/or shape the particle beam to generate a second cross-over of the particle beam, the second cross-over being arrangeable on the object, using the at least one objective lens, wherein the at least one objective lens is controlled with a predefinable value of an objective lens current using the at least one control device; and
deflect the particle beam to a position associated with the defined distance along an optical axis of the particle beam apparatus depending on the defined distance using the at least one deflection device, wherein the position of the particle beam is arranged along the optical axis within the second deflection unit, and wherein the at least one deflection device is controlled with control signals using the at least one control device of the particle beam apparatus—in such a way that aberrations generated by the at least one objective lens are reduced.

18. The particle beam apparatus according to claim 17, wherein
the first deflection unit is arranged in the at least one objective lens on a side of the at least one objective lens directed towards the at least one beam generator, and wherein
the second deflection unit is arranged in the at least one objective lens on a side of the at least one objective lens directed towards the object.

19. The particle beam apparatus according to claim 17, wherein the particle beam apparatus has at least one of the following features:
at least one detector unit that detects interaction particles and/or interaction radiation resulting from an interaction of the particle beam with the object;
at least one acceleration device that accelerates the particles and/or a deceleration device that decelerates the particles in the particle beam apparatus.

20. The particle beam apparatus according to claim 17, wherein the particle beam apparatus has at least one of the following features:
a movable object holder, on which the object is arranged;
a movement device for moving that moves the objective lens.

21. The particle beam apparatus according to claim 17, wherein the at least one beam generator is a first beam generator and the particle beam is a first particle beam having first charged particles, wherein the at least one objective lens is a first objective lens that focuses the first particle beam on the object, and wherein the particle beam apparatus further comprises:
at least one second beam generator that generates a second particle beam having second charged particles; and
at least one second objective lens that focuses the second particle beam on the object.

22. The particle beam apparatus according to claim 17, wherein the particle beam apparatus is an electron beam apparatus and/or an ion beam apparatus.
